(19) United States
(12) Patent Application Publication
(10) Pub. No.: US 2025/0118633 A1
(43) Pub. Date: Apr. 10, 2025

(54) SEMICONDUCTOR ARRANGEMENT COMPRISING A SEMICONDUCTOR ELEMENT WITH AT LEAST ONE CONNECTION ELEMENT

(71) Applicant: Siemens AKtiengesellschaft, 80333 München (DE)

(72) Inventors: Alexander Hensel, Röttenbach (DE); STEFAN STEGMEIER, München (DE); CLAUS FLORIAN WAGNER, Nürnberg (DE); MICHAEL WOITON, Nürnberg (DE)

(73) Assignee: Siemens AKtiengesellschaft, 80333 München (DE)

(21) Appl. No.: 18/836,264

(22) PCT Filed: Jan. 12, 2023
(86) PCT No.: PCT/EP2023/050603

§ 371 Date: Aug. 6, 2024

(30) Foreign Application Priority Data
Feb. 7, 2022 (EP) 22155438.9

(51) Int. Cl. H01L 23/485; C23C 4/06; C23C 4/134; H01L 21/60; H01L 23/49

(52) U.S. Cl. CPC H01L 23/485; H01L 21/60; H01L 23/49; C23C 4/06; C23C 4/134

(57) ABSTRACT

A semiconductor arrangement includes a semiconductor element having a connection element, and a metallic contacting element connected flatly to the connection element of the semiconductor element by being sprayed onto the semiconductor element via a thermal spraying method involving atmospheric plasma spraying. The metallic contacting element incudes first and second particles which form a textured layer, with the first particles deformed in a planar-like manner and with the second particles being melted second particles, said first particles being at least five times larger than the second particles.

The invention relates to a semiconductor arrangement having a semiconductor element with at least one connection element, at least one metallic contacting element being connected over its surface area to the at least one connection element of the semiconductor element.

Furthermore, the invention relates to a power converter with at least one such semiconductor arrangement.

Moreover, the invention relates to a method for the production of a semiconductor arrangement having a semiconductor element with at least one connection element, at least one metallic contacting element being connected over its surface area to the at least one connection element of the power semiconductor.

Such semiconductor arrangements are used, for example, in a power converter. A power converter is understood to mean, for example, a rectifier, an inverter, a converter or a DC-DC converter. A semiconductor element of such a semiconductor arrangement can, inter alia, be designed as a transistor, in particular as an Insulated-Gate Bipolar Transistor (IGBT), field-effect transistor or bipolar transistor, triac, thyristor or diode. Aluminum wire bond technology is usually used to contact connection elements of such semiconductor elements. In particular, in modern construction and bonding technologies, such bonding connection means are often the life-limiting factor.

For example, copper wire bond technology promises a significantly longer service life, in particular due to a higher modulus of elasticity, elastic modulus for short, and higher electrical conductivity. However, this requires higher compressive forces during contacting, resulting in the risk of damage to semiconductor elements.

The published, unexamined patent application DE 10 2009 008 926 A1 relates to a method for creating a high-temperature and thermal shock-resistant connection of an assembly semiconductor and a semiconductor module using a temperature-applying method in which a metal powder suspension is applied to the areas of the individual semiconductor modules to be connected later, the suspension layer is dried by outgassing the volatile components and producing a porous layer, the porous layer is precompacted without complete sintering penetrating the suspension layer, and to obtain a fixed, electrically and thermally highly conductive connection of a semiconductor module on a connection partner from the group: substrate, further semiconductor or circuit carrier, the connection is a sintered connection produced without pressing pressure by increasing the temperature, which consists of a dried metal powder suspension which has undergone a first transport-resistant contact with the connection partner in a precompaction step, and has been solidified without pressure with temperature sintering.

The published, unexamined patent application DE 10 2015 205 704 A1 describes a contact arrangement of at least one semiconductor element, in particular a power semiconductor element. In this case, an electrical connection of the semiconductor element has a metallization made of Al or an Al alloy. Furthermore, the electrical connection is connected to at least one wire or ribbon bond made of Cu or a Cu alloy. A contact element is arranged between the at least one electrical connection and the wire or ribbon bond, which contact element is connected to the electrical connection by an underside and to the wire or ribbon bond by an upper side. The contact element also has at least two adjacent layers, the underside being formed from a layer of Al or an Al alloy and the contact element comprising at least one further layer of Cu or a Cu alloy, Ag or an Ag alloy and/or Ni or an Ni alloy.

The patent application US 2005/230820 A1 describes a power semiconductor arrangement having an electrically insulating and thermally conductive substrate, which is provided with structured metallization on at least one side, a cooling apparatus, which is in thermal contact with the other side of the substrate, at least one semiconductor element, which is arranged on the substrate and is electrically connected to the structured metallization, a completely or partially electrically insulating film having conductive structures, which is at least arranged on the side of the substrate supporting the at least one semiconductor element and which is laminated onto the substrate without cavities, including or excluding the at least one semiconductor element, and a clamping apparatus which exerts a force on the substrate locally and via the at least one semiconductor element, so that the substrate is pressed against the cooling facility.

The patent application EP 2 521 166 A1 describes a method for producing a semiconductor element comprising creating a wafer, applying structures of components to the wafer to form a wafer composite, applying a metal layer to the wafer, removing the metal layer in non-contact areas of the components, applying passivation edges to the edge areas of the components, applying the wafer to a film held by a tension ring, separating the components supported by the film from one another out of the wafer composite, placing a covering mask on areas of the individual components supported by the film which are not to be coated, applying a metal layer to the individual components masked with the mask, removing the mask and removing the components from the film and further treating the individual components in which a metal layer is applied to the individual components masked with the mask by means of thermal spraying.

The use of such sintered layers has the disadvantage that the different coefficients of expansion of the materials, in particular during thermal cycles, represent a high load. The result is a rapid failure at the interface.

The patent application EP 3 926 670 A1 describes a power semiconductor module with at least one power semiconductor element. In order to reduce the required installation space of the power semiconductor module and to increase its service life, it is proposed that the at least one power semiconductor element is in an electrically insulating and thermally conductive connection with a cooling element via a dielectric material layer, the dielectric material layer resting flat on the surface of the cooling element and being non-positively connected to the cooling element by means of a first force acting orthogonally to the surface of the cooling element.

Against this background, it is an object of the present invention to increase the service life of a semiconductor arrangement.

This object is achieved in the case of a semiconductor arrangement of the type mentioned at the outset in that at least one metallic contacting element is produced by being sprayed onto the semiconductor element by means of a thermal spraying method, the metallic contacting element comprising particles which form a textured layer.

Furthermore, the object is achieved according to the invention by a power converter with at least one such semiconductor arrangement.

Moreover, the object is achieved in a method of the type mentioned at the outset in that at least one metallic contacting element is produced by being sprayed onto the semiconductor element by means of a thermal spraying method, particles being sprayed on by means of which a textured layer of the metallic contacting element (10) is formed.

The advantages and preferred embodiments listed below with regard to the semiconductor arrangement can be applied analogously to the power converter and the method.

The invention is based on the consideration of increasing the service life of a semiconductor arrangement with a semiconductor element by producing a contacting element, for example a metallic layer, by spraying it onto the semiconductor element by means of a thermal spraying method. A thermal spraying method is a method in which spray additives, for example particles, are thrown onto a surface. The spray additives can be present, inter alia, as a rod, a wire, a suspension or a powder. These can be heated to a plastic or molten state. Such thermal spraying methods include atmospheric plasma spraying (APS), flame spraying (FS), high-velocity oxygen fuel/air fuel spraying (HVOF/HVAF), arc wire spraying (AWS) and cold gas spraying (CS). In this way, the metallic contacting element is connected over its surface area to the at least one connection element of the semiconductor element. Such a connection element can be a contact pad with a chip metallization. Such a contact pad can be provided, inter alia, for contacting the semiconductor element, for example via bonding connection means. The sprayed-on metallic contacting element can form a metallic layer which, for example, distributes compressive forces occurring during contacting, in particular during bonding, for example by means of ultrasonic bonding or laser welding bonding, so that cracks in the semiconductor are avoided. For example, the layer has a thickness in the range of 1 μm to 250 μm, in particular 5 μm to 100 μm. By reducing the formation of cracks, the service life of the semiconductor arrangement is increased. Due to the thermal spraying method and the resulting structure, the metallic contacting element has a higher porosity and a slight spring effect, in particular compared to a metal plate produced by melting metallurgy or sintering. The increased porosity has a tolerance-compensating effect in the case of pressure connection. In particular, during subsequent operation of the semiconductor element, for example when switching a semiconductor off and on, the different coefficients of expansion of the semiconductor and the metals used in the metallic contacting element can be compensated for by the slight spring effect. The metallic contacting element can therefore act as a buffer layer, which has a positive effect on the service life of the semiconductor arrangement.

The metallic contacting element comprises particles which form a textured layer. The particles contain, for example, copper and/or molybdenum. Such a textured layer is composed of particles which are at least partially flat due to deformation, as a result of which compressive forces acting on the layer are compensated. If, for example, during contacting, in particular during bonding, pressure is exerted on the textured layer arranged on the semiconductor element, any compressive forces occurring are leveled and passed on homogeneously to the semiconductor element, which has a positive effect on the service life of the semiconductor arrangement. Even during subsequent operation of the semiconductor arrangement, for example when switching a semiconductor arrangement off and on, the different coefficients of expansion are compensated by the textured layer.

Another embodiment provides that a bonding connection means, in particular copper bonding connection means, or a press contact is contacted with the connection element of the semiconductor element via a surface of the metallic contacting element. Such bonding connection means may be, inter alia, bonding wires or bonding tapes. A press contact can be designed, inter alia, as a conductor rail, also referred to as a busbar. Due to the structure of the metallic contacting element produced by the thermal spraying method, forces occurring due to the pressure connection of the press contact or wire bond are leveled, so that crack formation is reduced and the service life thus increased.

Another embodiment provides that the press contact is contacted with the connection element by means of a force acting, in particular, orthogonally to the surface of the metallic contacting element. In particular, a pressure contact by means of a busbar is, for example, more robust against cyclical stress compared to a bond connection, which additionally increases the service life of the semiconductor arrangement.

Another embodiment provides that the textured layer comprises first particles, in particular deformed in a planar-like manner, and melted second particles, the first particles being at least five times, in particular ten times, larger than the second particles. Due to their volume, the larger first particles take over a large part of the electrical property. The smaller melted second particles, which are also referred to as condensed metal vapor, define the mechanical properties. In particular, the melted second particles can form an intermediate matrix after solidification. Such a textured metallic layer can compensate for CTE mismatches and an improved distribution of forces can be achieved. In addition, cracks occurring through such textured metallic layers are not conducted directly into the semiconductor, as is generally known in rigid systems, but remain in the textured metallic layer. Any stresses that occur are reduced and/or cracks peter out. The latter can be achieved by significantly reducing the elastic modulus and yield strength compared to bulk copper (ETP-Cu).

Another embodiment provides that the first particles, which are deformed in particular in a planar-like manner, are connected to one another via the melted second particles. The smaller melted second particles thus act as adhesion agents, consequently defining the mechanical properties, in particular a elastic modulus, a yield strength, etc. This creates a spring system in which the smaller melted second particles connect the larger, first particles, which are deformed in a planar-like manner. As a result, CTE mismatches can be even better compensated and a further improved distribution of forces can be achieved.

Another embodiment provides that the particles have a size in the range of 1 μm to 100 μm, in particular 5 μm to 25 μm, and/or are sprayed at a speed of 50 to 800 m/s. These parameters achieve good adhesion without damaging the semiconductor element.

Another embodiment provides that the metallic contacting element has a porosity in the range of 1% to 70%, in particular 2% to 50%. Such porosity of the metallic contacting element has a tolerance-compensating effect on pressure connections without the layer becoming mechanically unstable. This leads to relief of the semiconductor element, which has a positive effect on the service life of the semiconductor arrangement.

Another embodiment provides that the metallic contacting element additionally contains particles of a non-metallic inorganic material. Such a non-metallic inorganic material is, for example, a metal oxide such as aluminum oxide, a metal nitride such as aluminum nitride, a semiconductor such as silicon or a semiconductor oxide such as silicon oxide. By filling the metallic contacting element, the coefficients of expansion of the contacting element can be varied, so that the semiconductor element is relieved, which has a positive effect on the service life of the semiconductor arrangement. Compared to an increase in porosity, improved thermal conductivity is achieved.

Another embodiment provides that the contacting element has a material gradient. Such a material gradient is an uneven distribution of at least two different materials and/or material or process parameters. For example, the contacting element contains molybdenum and copper, where a proportion of molybdenum increases toward the semiconductor element, while a copper component increases away from the semiconductor element, resulting in a stepless reduction in the coefficient of expansion of the contacting element toward the semiconductor element. Furthermore, a material gradient can be produced by varying material parameters. The material parameters can be influenced by process parameters of the thermal spraying method, for example the particle velocity, the particle size, the temperature, the atmosphere, etc. This results in different properties depending on the location. For example, the porosity, the degree of melting, the type of particle deformation, in particular depending on the distance from the semiconductor element, can be varied by changing process parameters. Increasing the porosity toward the semiconductor element can reduce the load on it.

Another embodiment provides that the semiconductor element is designed as a vertical semiconductor element, at least two metallic contacting elements being arranged on opposite sides of the vertical semiconductor element. A vertical semiconductor element may be, inter alia, an IGBT. Such an arrangement makes it possible to achieve leveling on both sides, which in addition has a positive effect on the service life.

The invention is described and explained in more detail hereinafter with reference to the exemplary embodiments shown in the figures, in which:

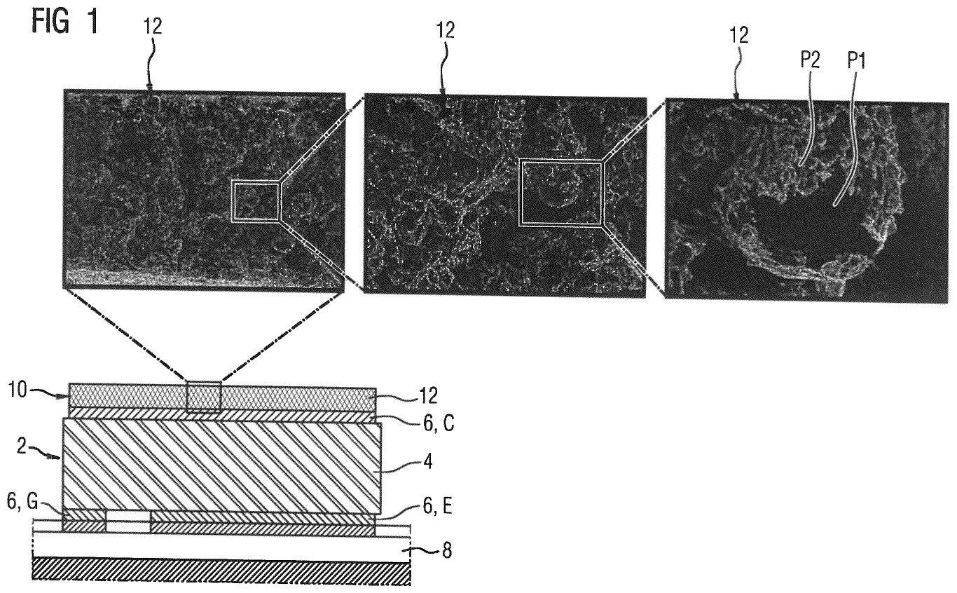

FIG. 1 shows a diagrammatic view of a semiconductor arrangement with a semiconductor element,

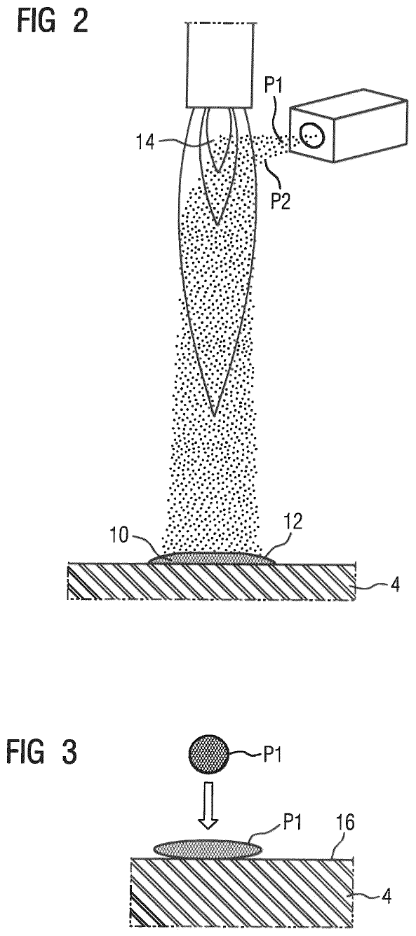

FIG. 2 shows a diagrammatic view of a thermal spraying method,

FIG. 3 shows a diagrammatic view of a typical deformation of a metallic particle on impact with a surface of a semiconductor element, plan view,

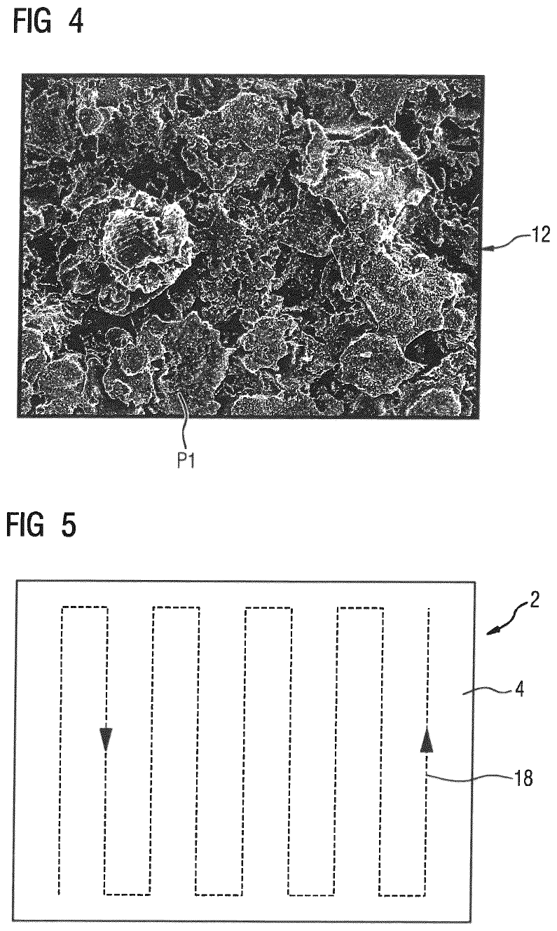

FIG. 4 shows an REM image of deformed metallic particles in a

FIG. 5 shows a diagrammatic view of a meandering spray path

geometry,

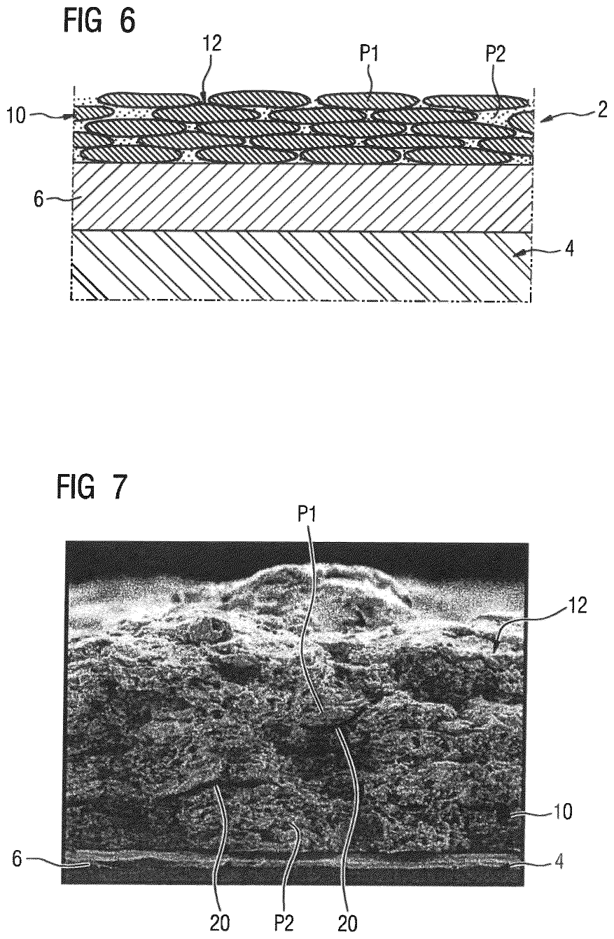

FIG. 6 shows an enlarged diagrammatic view of a semiconductor arrangement with a textured layer,

FIG. 7 shows an REM image of a textured layer in a side view,

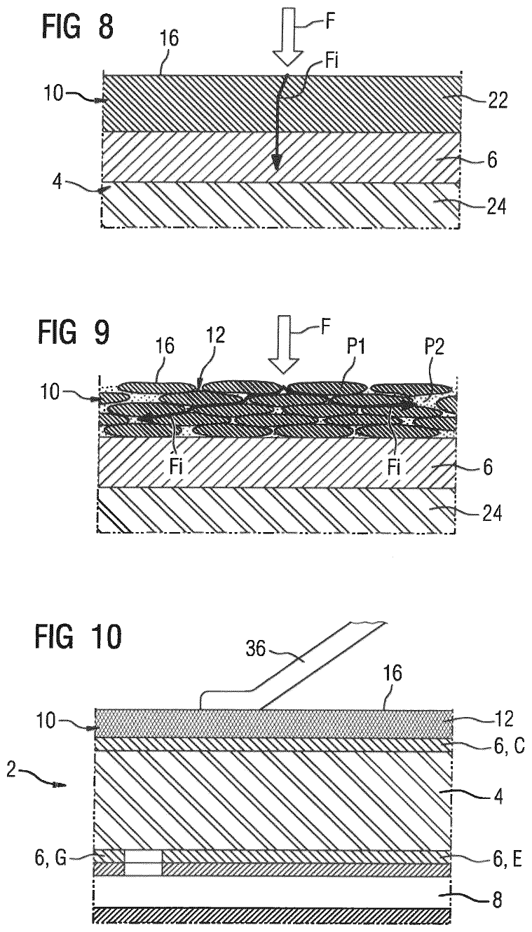

FIG. 8 shows a diagrammatic view of a force transmission into a semiconductor element over a standard copper layer,

FIG. 9 shows a diagrammatic view of a force transmission into a semiconductor element over a textured layer,

FIG. 10 shows a diagrammatic view of a semiconductor arrangement with a bonding connection means,

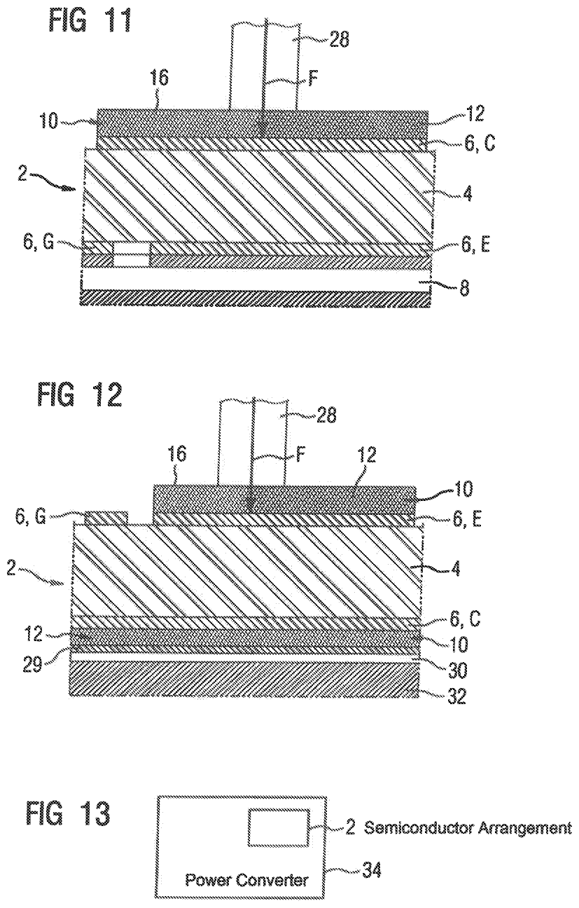

FIG. 11 shows a diagrammatic view of a semiconductor arrangement with a press contact,

FIG. 12 shows a diagrammatic view of a semiconductor arrangement with contacting elements arranged on both sides on the semiconductor element, and

FIG. 13 shows a diagrammatic view of a power converter.

The exemplary embodiments explained hereinafter are preferred embodiments of the invention. In the exemplary embodiments, the described components of the embodiments each represent individual features of the invention which are to be considered independently of one another and which also develop the invention independently of one another and are thus also to be regarded as part of the invention individually or in a combination other than that shown. In addition, the embodiments described can also be supplemented by other features of the invention already described.

The same reference characters have the same meaning in the different figures.

FIG. 1 shows a diagrammatic view of a semiconductor arrangement 2 with a semiconductor element 4. The semiconductor element 4 is exemplarily embodied as an Insulated-Gate Bipolar Transistor (IGBT). Further examples of such semiconductor elements 4 are other types of transistors such as field effect transistors and bipolar transistors as well as triacs, thyristors and diodes. The semiconductor element 4 can be designed as a semiconductor substrate using silicon or a wide band gap semiconductor, for example silicon carbide (SiC) or gallium nitride (GaN). The IGBT comprises connection elements 6 which are designed as a gate terminal G, a collector terminal C and an emitter terminal E. The connection elements 6 each comprise a contact pad with a chip metallization, which for example contains AlSiCu. The contact pads are provided for contacting the semiconductor element 4, inter alia, via bonding connection means. By way of example, the gate terminal G and the emitter terminal E are in contact on a substrate 8, which may be designed, inter alia, as a DCB substrate. For example, the gate terminal G and the emitter terminal E are integrally bonded to a structured metallization of the substrate 8, in particular via a soldered connection and/or a sintered connection. Alternatively, the connection to the structured metallization of the substrate 8 takes place on the collector side.

On a side facing away from the substrate 8, a metallic contacting element 10 is connected over its surface area to the collector terminal C of the semiconductor element 4. The metallic contacting element 10 is produced by means of a thermal spraying method, particles P1, P2 containing, for example copper and/or molybdenum, being sprayed onto the semiconductor element 4. The particles P1, P2 form a textured metallic layer 12, which, for example, has a thickness in the range of 1 μm to 250 μm, in particular 5 μm to 100 μm. A detail of the textured metallic layer 12 is shown in FIG. 1 as an REM image at various magnifications. The REM image was considered in order to better clarify its properties. FIG. 1 shows a textured copper or molybdenum layer by way of example. Such a textured layer 12 is composed of particles P1, P2, which are at least partially designed in a planar-like manner due to deformation. For example, the textured layer 12 comprises first particles P1 deformed in a planar-like manner and melted second particles P2, the first particles P1 being at least five times, in particular ten times, larger than the second particles P2. Due to their volume, the larger first particles P1 take over a large part of the electrical property. The smaller melted second particles P2, which are also referred to as condensed metal vapor, act as adhesion agents and thus define the mechanical properties, in particular a elastic modulus, a yield strength, etc. Thus, a spring system is formed in which the smaller melted second particles P2 connect the larger first particles P1 deformed in a planar-like manner. CTE mismatches can be compensated by such a textured metallic layer 12, and an improved distribution of forces can be achieved. In addition, cracks occurring through such textured metallic layers 12 are not conducted directly into the semiconductor, as is generally known in rigid systems, but remain in the textured metallic layer 12. Any stresses that occur are reduced and/or cracks peter out. The latter can be achieved by significantly reducing the elastic modulus and yield strength compared to bulk copper (ETP-Cu). This can be achieved, in particular in the case of a textured copper or molybdenum layer, with a higher proportion of O₂.

Compressive forces are compensated by such textured layers 12. If, for example, pressure is exerted during contacting, in particular during bonding, any compressive forces that occur are leveled by the textured layers 12 and passed on homogeneously to the semiconductor element 4. The different coefficients of expansion of the semiconductor (Si, GaN, SiC 3-7 ppm) and the metals (copper 17-18 ppm, aluminum 24 ppm) are also strongly compensated by their spring effect during subsequent operation of the semiconductor element 4, for example when switching a power semiconductor on and off. The metallic contacting element 10 thus acts as a buffer layer. As is generally known from the literature, copper tends to diffusion and grain boundary growth only at higher temperatures (>250° C.), as a result of which the spring effect described lasts longer and the property of the textured layer 12 can be used for a long time in the product life.

FIG. 2 shows a diagrammatic view of a thermal spraying method, a textured layer 12 of a metallic contacting element 10 being formed on a semiconductor element 4 by spraying on particles P1, P2. A thermal spraying method is a method in which spray additives, for example particles, are thrown onto a surface. The spray additives can be heated to a plastic or molten state. Such thermal spraying methods include atmospheric plasma spraying (APS), flame spraying (FS), high-velocity oxygen fuel/air fuel spraying (HVOF/HVAF), arc wire spraying (AWS) and cold gas spraying (CS).

As shown in FIG. 2, the impinging particles P1, P2, for example copper particles and/or molybdenum particles, form a layer on the surface of the semiconductor element 4, which, as described in FIG. 1, comprises so-called “splats”, i.e., on impact, in particular flat, flattened first particles P1. A thermal and/or kinetic energy source 14, which can be a plasma, a combustion flame, an arc, a laser, an explosion or a heated gas is used to apply the particles P1, P2. The spray additives can be present, inter alia, as a rod, a wire, a suspension or a powder.

FIG. 3 shows a diagrammatic view of a typical deformation of a metallic particle P1 on impact with a surface 16 of a semiconductor element 4. The particle P1 is greatly deformed by its velocity, which for example is in the range of 50 m/s to 800 m/s, and its softened state, as a result of which a flat shape is achieved. This effect is called a splattering effect and leads to high adhesion due to the wetting of a large surface.

FIG. 4 shows an REM image of deformed metallic particles P1 in a plan view. The metallic particles P1 which are deformed in a planar-like manner form a textured layer 12 which has the properties described in FIG. 1.

FIG. 5 shows a diagrammatic view of a meandering spray path geometry 18 when applying the particles P1, P2 to the semiconductor element 4. The sample, for example the semiconductor arrangement 2, is typically moved below a plasma beam by means of robotics. During the meandering spraying process, a layer overlap occurs in particular, a plurality of coating transitions being carried out so that strongly textured layer properties are achieved.

FIG. 6 shows an enlarged diagrammatic view of a semiconductor arrangement 2 with a textured layer 12 which forms the contacting element 10 connected to the connection element 6 of the semiconductor element 4. The textured layer 12 can contain, inter alia, copper and/or molybdenum particles and comprises first particles P1, which are deformed in a planar-like manner, and melted second particles P2, which are also referred to as condensed metal vapor. As described in FIG. 1, the larger first particles P1 take over a large part of the electrical properties due to their volume, while the smaller melted second particles P2, which are also referred to as condensed metal vapor, act as adhesion agents. The further embodiment of the semiconductor arrangement 2 in FIG. 6 corresponds to that in FIG. 1.

FIG. 7 shows an REM image of a textured layer 12 in a side view. The textured layer structure means that cracks 20, which can be produced, inter alia, due to pressure or thermal tension, are predominantly horizontal. This significantly relieves the semiconductor element 4 located underneath. In particular, IGBTs and other silicon-based semiconductor elements 4 react very sensitively to vertically introduced cracks 20, which can easily spread further in the silicon of the IGBT, due to their typical silicon orientation, for example 100. The further embodiment of the textured layer 12 in FIG. 7 corresponds to that in FIG. 6.

FIG. 8 shows a diagrammatic view of a force transmission Fi into a semiconductor element 4 over a standard copper layer 22 under the influence of a force F acting perpendicularly to the surface 16 as an example. The force F is introduced almost vertically into the semiconductor substrate 24, for example silicon, of the semiconductor element 4.

FIG. 9 shows a diagrammatic view of a force transmission Fi into a semiconductor element 4 over a textured layer 12. The perpendicular force F is essentially dissipated horizontally. This results in the force F being distributed by the essentially horizontal force transmission Fi or the pressure being homogenized, i.e., the pressure is distributed over a larger area and a risk of pressure peaks is minimized. The particles P1, P2 can rearrange themselves, which additionally relieves the semiconductor element 4, in particular the semiconductor substrate 24.

FIG. 10 shows a diagrammatic view of a semiconductor arrangement 2 with a bonding connection means 26, which is designed as a bond wire or bond tape, for example. The textured layer structure results in any force occurring during the bonding process being dissipated essentially horizontally.

Furthermore, the textured layer 12 of the contacting element 10 has a material gradient, i.e., an uneven distribution of at least two different materials and/or material or process parameters. For example, the textured layer 12 contains molybdenum (Mo) and copper (Cu), with a proportion of molybdenum increasing toward the semiconductor element 4, while a proportion of copper decreases away from the semiconductor element 4. This leads to a reduction in the coefficient of expansion of the contacting element 10 to the semiconductor element 4, in particular in a stepless manner.

Furthermore, a material gradient can be produced by varying material parameters. The material parameters can be influenced by process parameters of the thermal spraying method, for example the particle velocity, the particle size, the temperature, the atmosphere, etc. This leads to different properties depending on the location. For example, the porosity, the degree of melting, the type of particle deformation, in particular depending on the distance from the semiconductor element 4, can be varied by changing process parameters. In particular, such properties can be varied depending on the location via a plurality of, in particular at least partially overlapping, spray lanes with different process parameters. The further embodiment of the semiconductor arrangement 2 in FIG. 10 corresponds to that in FIG. 1.

FIG. 11 shows a diagrammatic view of a semiconductor arrangement 2 with a press contact 28. Such a press contact 28 can be, inter alia, a conductor rail, which is also called a busbar. The press contact 28 is contacted with the connection element 10 by means of a force F acting orthogonally to the surface 16 of the metallic contacting element 10. The textured layer structure of the metallic contacting element 10 results in the force F acting perpendicularly being dissipated essentially horizontally. The further embodiment of the semiconductor arrangement 2 in FIG. 11 corresponds to that in FIG. 10.

FIG. 12 shows a diagrammatic view of a semiconductor arrangement 2 with metallic contacting elements 10 arranged on both sides on the semiconductor element 4, each of which has a textured layer 12 and is integrally bonded to the connection elements 6 of the semiconductor element 4 by means of the thermal spraying method. On the collector side, the semiconductor element 4 is connected via the metallic contacting element 10 to a metallization 29, which is connected via a dielectric material layer 30 in an electrically insulating and thermally conductive manner to a cooling element 32, which is designed, for example, as a heat sink. The gate G can be connected, inter alia, via a bond connection, for example to a driver circuit. The dielectric material layer 30 has a ceramic material, for example aluminum nitride or aluminum oxide, or an organic material, for example a polyamide, and lies over its surface area on the cooling element 32. In particular, the semiconductor element 4 lies floating on the dielectric material layer 30 via the metallic contacting elements 10, a non-positive connection being produced by the press contact 28. Via the contacting element 10 connected on the collector side to the semiconductor element 4, forces are distributed to the metallization 29, to the dielectric material layer 30 and to the cooling element 32, so that good leveling also takes place here.

FIG. 13 shows a diagrammatic view of a power converter 34, which by way of example comprises a semiconductor arrangement 2.

In summary, the invention relates to a semiconductor arrangement 2 comprising a semiconductor element 4 with at least one connection element 6, at least one metallic contacting element 10 being connected over its surface area to the at least one connection element 6 of the semiconductor element 4. In order to increase the service life of the semiconductor arrangement 2, it is proposed that the at least one metallic contacting element 10 is produced by being sprayed onto the semiconductor element 4 by means of a thermal spraying method.

1.-16. (canceled)

17. A semiconductor arrangement, comprising:
a semiconductor element including a connection element; and
a metallic contacting element connected flatly to the connection element of the semiconductor element by being sprayed onto the semiconductor element via a thermal spraying method involving atmospheric plasma spraying, said metallic contacting element comprising first and second particles which form a textured layer, with the first particles deformed in a planar-like manner and with the second particles being melted second particles, said first particles being at least five times larger than the second particles.

18. The semiconductor arrangement of claim 17, wherein the first particles are at least ten times larger than the second particles.

19. The semiconductor arrangement of claim 17, further comprising a bonding connection, in particular copper bonding connection, or a press contact in contact with the connection element of the semiconductor element via a surface of the metallic contacting element.

20. The semiconductor arrangement of claim 19, wherein the press contact is in contact with the connection element via a force.

21. The semiconductor arrangement of claim 20, wherein the force acts orthogonally to the surface of the metallic contacting element.

22. The semiconductor arrangement of claim 17, wherein the first particles are connected to one another via the melted second particles.

23. The semiconductor arrangement of claim 17, wherein the first and second particles have a size in a range of 1 μm to 100 μm, in particular 5 μm-25 μm, and/or are sprayed at a speed of 50 to 800 m/s.

24. The semiconductor arrangement of claim 17, wherein the metallic contacting element has a porosity in a range of 1% to 70%, in particular 2% to 50%.

25. The semiconductor arrangement of claim 17, wherein the metallic contacting element contains further particles of a non-metallic inorganic material.

26. The semiconductor arrangement of claim 17, wherein the metallic contacting element has a material gradient.

27. A power converter, comprising a semiconductor arrangement, said semiconductor arrangement comprising a semiconductor element including a connection element, and a metallic contacting element connected over its surface area to the connection element of the semiconductor element by being sprayed onto the semiconductor element via a thermal spraying method involving atmospheric plasma spraying, said metallic contacting element comprising first and second particles which form a textured layer, with the first particles deformed in a planar-like manner and with the second particles being melted second particles, said first particles being at least five times larger than the second particles.

28. A method for the production of producing a semiconductor arrangement, the method comprising:
forming a textured layer of a metallic contacting element for connection of the metallic contacting element flatly upon a connection element of a semiconductor element by spraying first and second particles via a thermal spraying method onto the semiconductor element, with the first particles being at least five times larger than the second particles,
wherein the textured layer is formed by deformation of the first particles and melting of the second particles, and
wherein atmospheric plasma spraying is used as the thermal spraying method.

29. The method of claim 28, wherein the first particles are at least ten times larger than the second particles.

30. The method of claim 28, wherein the textured layer is deformed in a planar-like manner

31. The method of claim 28, further comprising contacting a bonding connection or a press contact via a surface of the metallic contacting element with the connection element of the semiconductor element.

32. The method of claim 31, wherein the press contact is in contact with the connection element via a force acting in particular orthogonally to the surface of the metallic contacting element.

33. The method of claim 28, further comprising connecting the first particles to one another via the melted second particles.

34. The method of claim 28, wherein the first and second particles have a size of 1 μm to 100 μm, in particular 5 μm-25 μm, and/or are sprayed at a speed of 50 to 800 m/s.

35. The method of claim 28, wherein the first and second particles are sprayed on in a meandering manner.

36. The method of claim 35, wherein a layer overlap occurs as the first and second particles are sprayed on in the meandering manner.
